(19) United States
(12) Patent Application Publication
(10) Pub. No.: US 2014/0060899 A1
(43) Pub. Date: Mar. 6, 2014

(54) PREPREG, COPPER CLAD LAMINATE, AND PRINTED CIRCUIT BOARD

(71) Applicant: SAMSUNG ELECTRO-MECHANICS CO., LTD., Gyunggi-do (KR)

(72) Inventors: Jung Hwan Park, Gyunggi-do (KR); Keung Jin Sohn, Gyunggi-do (KR); Tae Eun Chang, Gyunggi-do (KR)

(73) Assignee: SAMSUNG ELECTRO-MECHANICS CO., LTD., Gyunggi-do (KR)

(21) Appl. No.: 13/681,698

(22) Filed: Nov. 20, 2012

(30) Foreign Application Priority Data
Aug. 31, 2012 (KR) 10-2012-0096480

(51) Int. Cl. H05K 1/03; B32B 15/08; B32B 15/09; B32B 15/098; B32B 7/02; B32B 15/088

(52) U.S. Cl. CPC H05K 1/032; B32B 7/02; B32B 15/088; B32B 15/09; B32B 15/098; B32B 15/08
USPC 174/255; 428/212

(57) ABSTRACT

Disclosed herein are prepreg, a copper clad laminate (CCL), and a printed circuit board. When a reinforcing member formed of organic fiber including a liquid crystal polymer resin or a super engineering resin and a base resin having the same component as the reinforcing member are used, a coefficient of thermal expansion (CTE) and rigidity may be adjusted. In addition, during an operation of a semiconductor chip mounted on the printed circuit board, the semiconductor chip and the printed circuit board expand and contract due to heat by as much as similar degrees, and thus, the reliability of a solder joint may be enhanced. Moreover, fiber protrusion failure may be prevented compared with a case a via hole is processed by using a CO₂ laser drill, thereby minimizing substrate failures.

### CROSS REFERENCE TO RELATED APPLICATION

This application claims the benefit of Korean Patent Application No. 10-2012-0096480, filed on Aug. 31, 2012, entitled “Prepreg, Copper Clad Laminate, and Printed Circuit Board”, which is hereby incorporated by reference in its entirety into this application.

### BACKGROUND OF THE INVENTION

1. Technical Field

The present invention relates to prepreg, a copper clad laminate (CCL), and a printed circuit board.

2. Description of the Related Art

Recently, multi-functional and high speed electronic products have been rapidly developed. To satisfy this trend, semiconductor chips have been rapidly developed. Semiconductor chips have been rapidly developed to exceed Moore's law whereby an amount of data capable of being stored in a semiconductor chip doubles every 18 months. Thus, semiconductor chip mounting substrates connecting a semiconductor chip and a main board have very rapidly developed. Requirements for the development of semiconductor chip mounting substrates are closely related to a high-speed and high-integration semiconductor chip mounting substrate. To satisfy the requirements, semiconductor chip mounting substrates need to be developed to be light, thin, short, and small, to have fine circuits, to have excellent electrical properties and high reliability, and to have a structure for transferring signals at high speed.

According to requirements for light, thin, short, small, high-speed, and high-integration semiconductor chip mounting substrates for directly connecting a semiconductor chip and a main board, problems of semiconductor chip mounting substrates become more serious in terms of warpage due to heat generated during an operation of the semiconductor chip, solder joint failure due to coefficient of thermal expansion (CTE) mismatch between a semiconductor chip mounting substrate and a semiconductor chip, and so on. To overcome these problems, many technologies have been developed. In order to obtain high-integration and high-speed semiconductor chip mounting substrates, insulating members such as a copper clad laminate (CCL), prepreg, and so on, which are main members of a semiconductor chip mounting substrate, need to be first developed.

A conventional multi-layer printed circuit board uses glass fiber as a reinforcing member. For example, E-glass fiber or the like has been used as an example of the glass fiber is E-glass fiber.

Glass fiber is processed in the form of cloth, is impregnated with an insulating layer formed of a thermosetting resin composition, and then is processed to result in a CCL. An inner core printed circuit board is manufactured by using the CCL, and then, insulating layer sheets for build-up, which are formed of a thermosetting resin composition in a B-stage state, are stacked on both surfaces of the inner core printed circuit board to manufacture a multi-layer printed circuit board. However, as described above, a CTE of the multi-layer printed circuit board is very different from a CTE of a semiconductor chip. Due to this difference, in a reliability test such as a temperature cycle test for a flip-chip contact using solder, which has is with out lead in order to overcome current environmental problems, a multi-layer printed circuit board contracts in longitudinal and transverse directions when heated, crack or peel failures of an unleaded solder, break failures of a semiconductor chip, and so on can be generated.

Patent Document 1 for overcoming the problem discloses a method of forming an organic insulating layer having a low CTE as an outermost layer of a multi-layer printed circuit board having a CTE of 13 to 20 ppm/° C. in order to reduce stress. Patent Document 1 suggests the multi-layer printed circuit board using prepreg in which a reinforcing member including aramid fiber cloth of a CTE of about 9 ppm/° C. is impregnated with a thermosetting resin. However, Patent Document 1 does not suggest a detailed result of a reliability test in the detailed description disclosing an embodiment. In addition, when a thermal buffer organic insulating layer sheet having a CIE of 6 to 12 ppm/° C. is integrally adhered to a multi-layer printed circuit board, the thermal buffer organic insulating layer sheet becomes tight and expands due to a great CTE of the integrated multi-layer printed circuit board. Thus, a total CTE of the integrated multi-layer printed circuit board can exceed 10 ppm/° C.

In addition, Patent Document 2 discloses a method of manufacturing an insulating sheet by preparing polybenzoxazole or polyaramid as the organic fiber used as a reinforcing member and impregnating the organic fiber with liquid crystal polyester. However, in the method disclosed in Patent Document 2, a core layer is melted while being compressed during the manufacture of prepreg and a CCL, and thus, spaces between circuits are not completely filled, and unevenness is formed on a circuit layer along unevenness of resin. In addition, when a via for interconnection between layers is processed, the organic fiber is not completely removed, thereby causing circuit failure.

Patent Document 1: Japanese Patent Laid-Open Publication No. 2001-274556

Patent Document 2: Korean Patent Laid-open Publication No. 2009-0099676

### SUMMARY OF THE INVENTION

According to the present invention, unlike in a conventional method, a reinforcing member formed of organic fiber including a liquid crystal polymer resin or a super engineering resin and a base resin having substantially the same heat resistance to the reinforcing member. In this case, a melting point of a resin included in the reinforcing member is higher than a melting point of the base resin by as much as 10 to 30° C. Thus, fiber protrusion failure may be prevented compared with a case a via hole is processed by using a CO₂ laser drill, thereby minimizing errors. In addition, a coefficient of thermal expansion (CTE) of a raw material of a substrate is reduced to reduce warpage failure.

Thus, the present invention has been made in an effort to provide prepreg including a reinforcing member formed of a liquid crystal polymer resin or a super engineering resin and a base resin including the same resin component as the reinforcing member.

Further, the present invention has been made in an effort to provide a copper clad laminate (CCL) obtained by stacking a copper thin film on the prepreg.

Further, the present invention has been made in an effort to provide a printed circuit board including the CCL.

According to a first preferred embodiment of the present invention, there is provided prepreg including: a reinforcing member including organic fiber formed of a first liquid crystal polymer resin or a first super engineering resin; and a base resin layer formed on the reinforcing member and including a second liquid crystal polymer resin or a second super engineering resin, wherein a melting point of the reinforcing member is higher than a melting point of the base resin layer by as much as 10 to 30° C.

In the first preferred embodiment of the present invention, the liquid crystal polymer resin may include an aromatic polyester resin.

In the first preferred embodiment of the present invention, the super engineering resin may include polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

In the first preferred embodiment of the present invention, a coefficient of thermal expansion (CTE) of the reinforcing member in longitudinal and transverse directions may be −20 to 9 ppm/T.

In the first preferred embodiment of the present invention, a coefficient of thermal expansion (CTE) of the base resin layer in longitudinal and transverse directions may be −20 to 9 ppm/T.

In the first preferred embodiment of the present invention, the reinforcing member and the base resin layer may be formed of the same resin.

According to a second preferred embodiment of the present invention, there is provided a copper clad laminate (CCL), including: a reinforcing member including organic fiber formed of a first liquid crystal polymer resin or a first super engineering resin; a base resin layer formed on the reinforcing member and including a second liquid crystal polymer resin or a second super engineering resin; and a metal layer formed on the base resin layer, wherein a melting point of the reinforcing member is higher than a melting point of the base resin layer by as much as 10 to 30° C.

In the second preferred embodiment of the present invention, the liquid crystal polymer resin may include an aromatic polyester resin.

In the second preferred embodiment of the present invention, the super engineering resin may include polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

In the second preferred embodiment of the present invention, a coefficient of thermal expansion (CTE) of the reinforcing member in longitudinal and transverse directions may be −20 to 9 ppm/° C.

In the second preferred embodiment of the present invention, a coefficient of thermal expansion (CTE) of the base resin layer in longitudinal and transverse directions may be −20 to 9 ppm/° C.

In the second preferred embodiment of the present invention, the reinforcing member and the base resin layer may be formed of the same resin.

According to a third preferred embodiment of the present invention, there is provided a printed circuit board, including: a reinforcing member including organic fiber formed of a first liquid crystal polymer resin or a first super engineering resin; a base resin layer formed on the reinforcing member and including a second liquid crystal polymer resin or a second super engineering resin; and a circuit pattern formed by etching a metal layer formed on the base resin layer, wherein a melting point of the reinforcing member is higher than a melting point of the base resin layer by as much as 10 to 30° C.

In the third preferred embodiment of the present invention, the liquid crystal polymer resin may include an aromatic polyester resin.

In the third preferred embodiment of the present invention, the super engineering resin may include polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

In the third preferred embodiment of the present invention, a coefficient of thermal expansion (CTE) of the reinforcing member in longitudinal and transverse directions may be −20 to 9 ppm/° C.

In the third preferred embodiment of the present invention, a coefficient of thermal expansion (CTE) of the base resin layer in longitudinal and transverse directions may be −20 to 9 ppm/° C.

In the third preferred embodiment of the present invention, the reinforcing member and the base resin layer may be formed of the same resin.

Hereinafter, the features and the merits of the present invention will be described more fully from the description of the preferred embodiments.

### DESCRIPTION OF THE PREFERRED EMBODIMENTS

While describing the embodiments, detailed descriptions about related well-known functions or configurations that may diminish the clarity of the points of the embodiments of the present invention are omitted.

The objects, features, and advantages of the present invention will be more clearly understood from the following detailed description of the preferred embodiments. Further, in the description of the present invention, when it is determined that the detailed description of the related art would obscure the gist of the present invention, the description thereof will be omitted.

According to an embodiment of the present invention, prepreg includes a reinforcing member and a base resin layer.

The reinforcing member includes organic fiber formed of a first liquid crystal polymer resin or a first super engineering resin. In more detail, the reinforcing member is manufactured in the form of cloth by using fiber that is formed of an organic polymer resin such as the first liquid crystal polymer resin or the first super engineering resin. The organic fiber may be manufactured via a spinning method of melting and spinning an organic polymer resin, a blow molding method of thermal-compressing a polymer resin and passing the polymer resin through a die having a predetermined size, or the like. When the melted organic polymer resin goes through a spinning outlet, many molecules are arranged and oriented side by side along a spinning axis and are very highly oriented. Thus, the intensity or coefficient of thermal expansion (CTE) of fiber may be reduced, and accordingly, an organic fiber having a desired CTE. The manufactured organic fiber may be formed in the form of cloth including organic components via a weaving process.

An example of the organic polymer resin used to manufacture the organic fiber is not almost limited. However, in consideration of CTE properties during the manufacture of a printed circuit board, a liquid crystal polymer resin or the like using aromatic polyester as base may be used. In addition, the organic fiber may be manufactured by using a super engineering resin that is not deformed at a mounting temperature of components used in the printed circuit board, that is, at a temperature of 240 to 260° C. and, that is, has a melting point or glass transition temperature of 280° C. or more. Among super engineering resins, a semi-crystal type polymer resin may be spun to manufacture the organic fiber. During the manufacture of the organic fiber, a CTE of the organic fiber may be adjusted via an orientation process. Examples of the super engineering resin may include polyphenylene sulfide (PPS), polyether ether ketone (PEEK), polyphthal amide (PPA), polysulfone (PSU), polyether imide (PEI), polyether sulfone (PES), polyphenyl sulfone (PPSU), polyamide imide (PAD, or the like.

In order to increase adhesion intensity between the resin member and resin, a surface of the reinforcing member may be processed via a known method, for example, silane coupling agent treatment, process treatment, corona treatment, various chemical treatments, blast treatment, or the like.

The thickness of the reinforcing member is not particularly limited, but may be 4 to 200 an, in detail, 10 to 150 μm.

The base resin layer may be formed by impregnating the reinforcing member with a base resin including a second liquid crystal polymer resin or a second super engineering resin. In this case, in order to minimize fiber protrusion and warpage failure, which occur during manufacture of a printed circuit board, it is advantageous that the base resin layer is manufactured by using an organic polymer resin exhibiting similar heat resistance properties to the organic polymer resin used as the reinforcing member, and thus, the base resin layer may be formed by using the same resin as the resin used for forming the reinforcing member. In this case, the similar heat resistance properties refer to the same CTE and melting points within a predetermined range.

That is, according to the present invention, a melting point of the organic polymer resin included in the base resin layer may be lower than a melting point of the organic polymer resin included in the reinforcing member by as much as 10 to 30° C. When a melting point difference between the base resin layer and the reinforcing member is smaller than 10° C., the reinforcing member is melted while being compressed during manufacture of prepreg and a copper clad laminate (CCL), and thus, a reinforcing effect is reduced. When a melting point difference between the base resin layer and the reinforcing member is greater than 30° C., problems such as fiber protrusion during a process of processing a via hole may arise.

In order to prepare a raw material having a lower CTE than a conventional substrate raw material, organic fiber may be manufactured by using a liquid crystal polymer resin or the like using aromatic polyester as base or a semi-crystal type polymer resin, for example, PPS, PEEK, PPA, PSU, PEI, PES, PPSU, PAI, or the like, and an insulating material is prepared by using a base resin layer having similar molecular compositions. Due to the molecular compositions, a CTE may be further reduced by orientation during manufacture of the organic fiber and the base resin layer. The organic polymer resin included in the reinforcing member and the base resin layer may have a CTE of −20 to 9 ppm/° C.

In particular, when the reinforcing member or the base resin layer are formed by using a resin such as PPS, PEEK, PPA, or the like having a melting point or glass transition temperature of 280° C. or more, the rigidity of the prepreg may be further increased.

Appropriate amounts of various additives may be added to the organic polymer resin included in the base resin layer as long as the additives may not affect target properties. For example, when the base resin layer is formed, various additives such as various thermosetting resins, thermoplastic resins, other resins, known organic and inorganic fillers, dye, pigment, thickening agents, antifoaming agents, dispersing agents, polishing agents, and so on may be added to the organic polymer resin.

The reinforcing member formed of the organic fiber is impregnated with a base resin via a similar method as a method of manufacturing a conventional substrate raw material to prepare an insulating material. That is, prepreg is manufactured by melting the base resin, injecting the base resin into an impregnation vessel, passing the reinforcing member through the impregnation vessel so as to adhere the base resin and the reinforcing member to each other, and then drying the resultant. The prepreg may be formed to have a desired thickness by applying releasing films to upper and lower surfaces of the manufactured prepreg and secondarily processing the resultant, that is, performing thermal compression on the resultant. In addition, instead of the releasing films, copper clads are applied to the upper and lower surfaces of the prepreg to manufacture a CCL.

A printed circuit board is manufactured via the same method as a conventional manufacturing method. First, a CCL including the organic fiber formed of organic polymer resin is used as a core substrate, a through hole is processed for interconnection between layers and then an internal layer circuit is formed via a general subtractive method or a semi-additive method and is plated with copper. An internal surface of the through hole such that upper and lower layers are connected to each other, and thus, electrical signals may be transferred.

Then, prepreg using the organic fiber formed of organic polymer resin is stacked on the core substrate where the through hole and the internal layer circuit is formed, a via hole is formed for interconnection between layers, and then an external layer is formed via a subtractive method or a semi-additive method. In this case, the via hole is plated with copper. If necessary, insulating materials may be repeatedly stacked and circuit may be formed to obtain a multi-layer printed circuit board.

Then, solder resist is coated on the substrate whereon the external layer circuit is formed, via a screen printing method or a roll-coating printing method, and then, a portion of the solder resist is removed from a portion of the substrate, to which a semiconductor chip is to be connected, via a photolithography method or the like. Surface treatment is performed on the portion from which the solder resist is removed to prevent a circuit from being oxidized.

According to a connecting method with a semiconductor chip, a solder bump may be formed via a solder screen method, a solder plating method, or the like.

According to the present invention, the prepreg and the CCL are manufactured by using the organic fiber, and thus, their CTEs and rigidities may be adjusted. In addition, during an operation of a semiconductor chip mounted on a printed circuit board, the semiconductor chip and the printed circuit board expand and contract due to heat by as much as similar degrees, and thus, the reliability of a solder joint may be enhanced.

In addition, according to the present invention, in the printed circuit board using the prepreg and the CCL, fiber protrusion failure may be reduced compared with a case the via hole is processed by using a CO₂ laser drill.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. Prepreg, comprising:
a reinforcing member comprising organic fiber formed of a first liquid crystal polymer resin or a first super engineering resin; and
a base resin layer formed on the reinforcing member and comprising a second liquid crystal polymer resin or a second super engineering resin,
wherein a melting point of the reinforcing member is higher than a melting point of the base resin layer by as much as 10 to 30° C.

2. The prepreg as set forth in claim 1, wherein the liquid crystal polymer resin comprises an aromatic polyester resin.

3. The prepreg as set forth in claim 1, wherein the super engineering resin comprises polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

4. The prepreg as set forth in claim 1, wherein a coefficient of thermal expansion (CTE) of the reinforcing member in longitudinal and transverse directions is −20 to 9 ppm/° C.

5. The prepreg as set forth in claim 1, wherein a coefficient of thermal expansion (CTE) of the base resin layer in longitudinal and transverse directions is −20 to 9 ppm/° C.

6. The prepreg as set forth in claim 1, wherein the reinforcing member and the base resin layer are formed of the same resin.

7. A copper clad laminate (CCL), comprising:
a reinforcing member comprising organic fiber formed of a first liquid crystal polymer resin or a first super engineering resin;
a base resin layer formed on the reinforcing member and comprising a second liquid crystal polymer resin or a second super engineering resin; and
a metal layer formed on the base resin layer,
wherein a melting point of the reinforcing member is higher than a melting point of the base resin layer by as much as 10 to 30° C.

8. The copper clad laminate (CCL) as set forth in claim 7, wherein the liquid crystal polymer resin comprises an aromatic polyester resin.

9. The copper clad laminate (CCL) as set forth in claim 7, wherein the super engineering resin comprises polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

10. The copper clad laminate (CCL) as set forth in claim 7, wherein a coefficient of thermal expansion (CTE) of the reinforcing member in longitudinal and transverse directions is −20 to 9 ppm/° C.

11. The copper clad laminate (CCL) as set forth in claim 7, wherein a coefficient of thermal expansion (CTE) of the base resin layer in longitudinal and transverse directions is −20 to 9 ppm/T.

12. The copper clad laminate (CCL) as set forth in claim 7, wherein the reinforcing member and the base resin layer are formed of the same resin.

13. A printed circuit board, comprising:
a reinforcing member comprising organic fiber formed of a first liquid crystal polymer resin or a first super engineering resin;
a base resin layer formed on the reinforcing member and comprising a second liquid crystal polymer resin or a second super engineering resin; and
a circuit pattern formed by etching a metal layer formed on the base resin layer,
wherein a melting point of the reinforcing member is higher than a melting point of the base resin layer by as much as 10 to 30° C.

14. The printed circuit board as set forth in claim 13, wherein the liquid crystal polymer resin comprises an aromatic polyester resin.

15. The printed circuit board as set forth in claim 13, wherein the super engineering resin comprises polyphenylene sulfide (PPS), polyether ether ketone (PEEK), polyphthal amide (PPA), polysulfone (PSU), polyether imide (PEI), polyether sulfone (PES), polyphenyl sulfone (PPSU), or polyamide imide (PAI).

16. The printed circuit board as set forth in claim 13, wherein a coefficient of thermal expansion (CTE) of the reinforcing member in longitudinal and transverse directions is −20 to 9 ppm/T.

17. The printed circuit board as set forth in claim 13, wherein a coefficient of thermal expansion (CTE) of the base resin layer in longitudinal and transverse directions is −20 to 9 ppm/T.

18. The printed circuit board as set forth in claim 13, wherein the reinforcing member and the base resin layer are formed of the same resin.
